(19) United States
(12) Patent Application Publication
(10) Pub. No.: US 2010/0164049 A1
(43) Pub. Date: Jul. 1, 2010

(54) IMAGE SENSOR AND METHOD FOR MANUFACTURING THE SAME

(76) Inventors: Jae Hyun Yoo, Incheon (KR); Jong Min Kim, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/647,694

(22) Filed: Dec. 28, 2009

(30) Foreign Application Priority Data
Dec. 30, 2008 (KR) 10-2008-0137477

(51) Int. Cl. H01L 31/00; H01L 31/18

(52) U.S. Cl. 257/461; 438/59; 257/E31.001

(57) ABSTRACT

Provided are an image sensor and a method for manufacturing the same. The image sensor comprises an active region including a photodiode region, a transistor region, and an active pattern; a photodiode; and a plurality of transistors. The active region is formed on a substrate. The active region is defined by a device isolation region. The photodiode region and the transistor region are formed in the active region. The photodiode is formed in the photodiode region. The plurality of transistors is formed on the transistor region. The active pattern connects the photodiode region to the transistor region at a second location.

### CROSS-REFERENCE TO RELATED APPLICATION

This application claims the benefit under 35 U.S.C. §119 of Korean Patent Application No. 10-2008-0137477, filed Dec. 30, 2008, which is hereby incorporated by reference in its entirety.

### BACKGROUND

The present disclosure relates to an image sensor and a method for manufacturing the same.

Image sensors are semiconductor devices which can convert optical images into electrical signals. Such image sensors can typically be classified as either Charge Coupled Device (CCD) image sensors or Complementary Metal Oxide Semiconductor (CMOS) image sensors (CIS).

A floating diffusion (FD) capacity sizing and doping control are often performed on a related-art image sensor to increase sensitivity and dynamic range.

However, the optimization of the above method has many restrictions in an FD design due to the trade-off relation between a stress leakage according to Length of Diffusion (LOD) and the FD capacitance and the trade-off relation between a doping concentration and the FD capacitance. Generally, as illustrated by the graph shown in FIG. 1, the related art FD structure has a tendency to show linear characteristics (line S) for a saturation voltage Vsat with respect to the intensity of incident light (lux).

For more improved characteristics of an image sensor, the characteristic curve L of FIG. 2 showing a high sensitivity in a low incident section l and a low sensitivity in a high incident section h, while showing a wide dynamic range is required.

In a related-art method to obtain such a characteristic curve, an operation change of a transfer transistor may be implemented using an additional memory or operation circuit. However, the additional circuit may cause consumption of the chip size, and may have an effect on the characteristics of the circuit itself.

### BRIEF SUMMARY

Embodiments provide an image sensor and a method for manufacturing the same, which can obtain improved optical characteristics by making changes in the device structure instead of the operational manner to obtain wide dynamic range characteristics.

In one embodiment, an image sensor comprises: an active region on a substrate, the active region being defined by a device isolation region; a photodiode region and a transistor region in the active region; a photodiode in the photodiode region; a plurality of transistors in the transistor region; and an active pattern connecting the photodiode region to the transistor region.

In another embodiment, a method for manufacturing an image sensor comprises: defining an active region on a substrate using a device isolation region, the active region comprising a photodiode region and a transistor region; forming a photodiode in the photodiode region; forming a transistor in the transistor region; and forming an active pattern connecting the photodiode region to the transistor region. According to an embodiment, the active pattern is formed when defining the active region.

The details of one or more embodiments are set forth in the accompanying drawings and the description below. Other features will be apparent from the description and drawings, and from the claims.

### BRIEF DESCRIPTION OF THE DRAWINGS

FIGS. 1 and 2 are graphs illustrating the characteristics of an image sensor.

FIG. 3 is a plan view illustrating an image sensor according to an embodiment.

FIG. 4 is an energy band diagram of an image sensor according to an embodiment.

FIG. 5 is a graph illustrating punch-through current with respect to PD potential.

FIG. 6 is a graph illustrating photo current with respect to luminance.

FIG. 7 is a graph illustrating PD potential with respect to luminance.

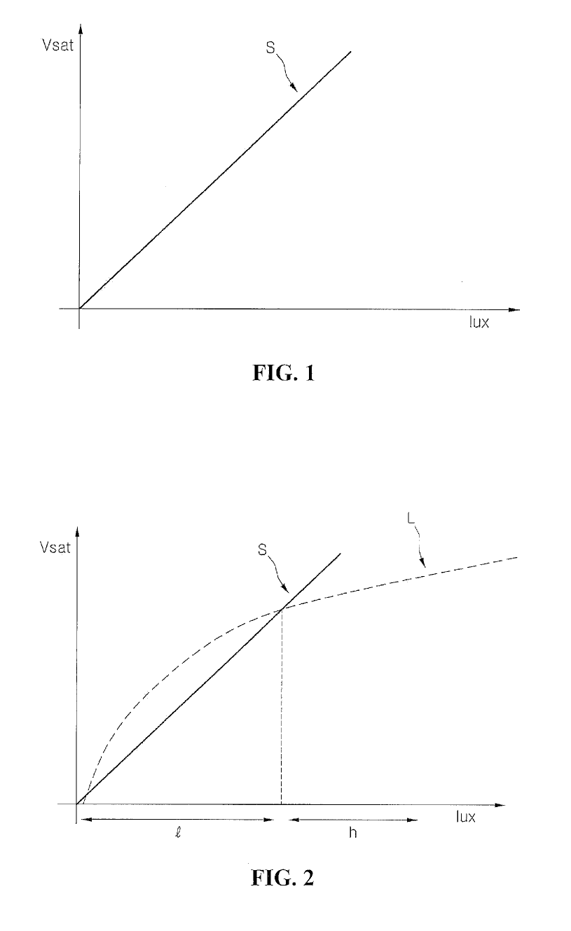

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

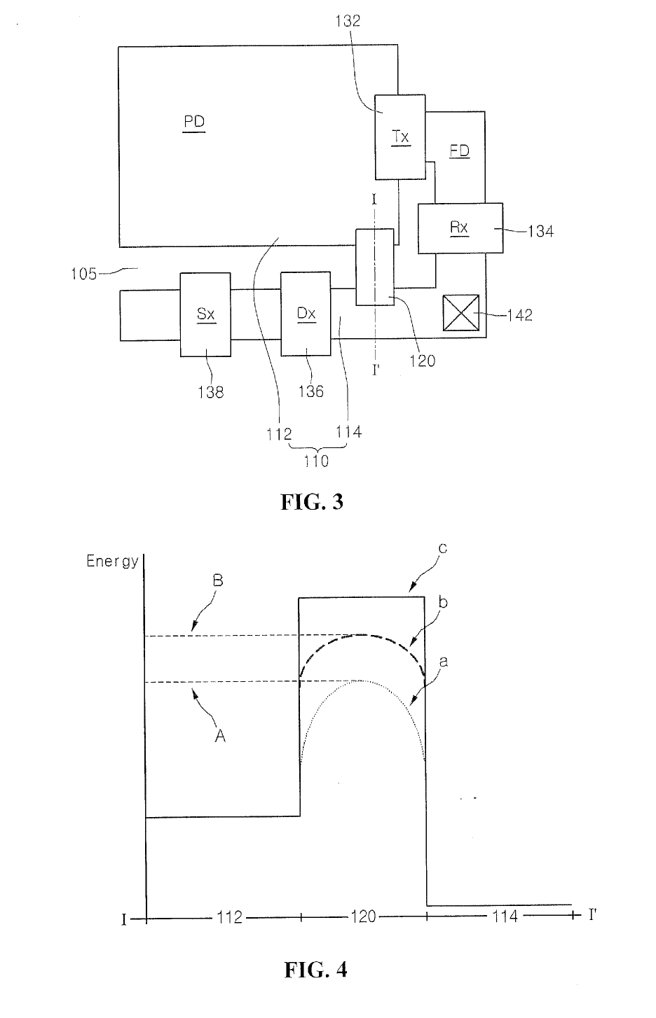

FIG. 3 is a plan view illustrating an image sensor according to an embodiment.

An image sensor according to an embodiment may include: an active region 110 on a substrate, the active region being defined by a device isolation region 105; a photodiode region 112 and a transistor region 114 in the active region 110; a photodiode PD in the photodiode region 112; a plurality of transistors in/on the transistor region 114; and an active pattern 120 connecting the photodiode region 112 to the transistor region 114.

A first conductive-type ion implantation may be performed on the active pattern 120. For example, N-type ions may be implanted into the active pattern 120, but is not limited thereto. The active region 110, including active pattern 120, can initially be of a second conductive type, such as when the substrate is a second conductive type or includes a second conductive type epitaxial layer. For example, the active region 110 and the active pattern can be P-type. The N-type ions can be implanted into the P-type active pattern 120.

According to one embodiment, the device isolation region 105 is not formed under the active pattern 120.

The active pattern 120 may serve as a potential barrier (provide a barrier potential) between the photodiode region 112 and the transistor region 114.

In one embodiment, the active pattern 120 may control the potential barrier using a doping concentration of the first conductive-type ion implantation.

In another embodiment, the active pattern 120 may control the potential barrier using a distance between the photodiode region 112 and the transistor region 114. For example, the distance between the photodiode region 112 and the transistor region 114 may be adjusted to substitute punch-through characteristics with Drain-Induced Barrier Lowering (DIBL) characteristics.

The transistor region 114 to which the active pattern 120 is connected may be a VDD region where a VDD contact 142 is formed, but is not limited thereto.

A structure is provided using the punch-through effect by expanding an active region of a related-art image sensor using the active pattern 120.

Thus, the added active pattern 120 has an energy barrier isolation structure different from a related-art STI isolation structure.

FIG. 4 shows an energy band diagram taken along line I-I′.

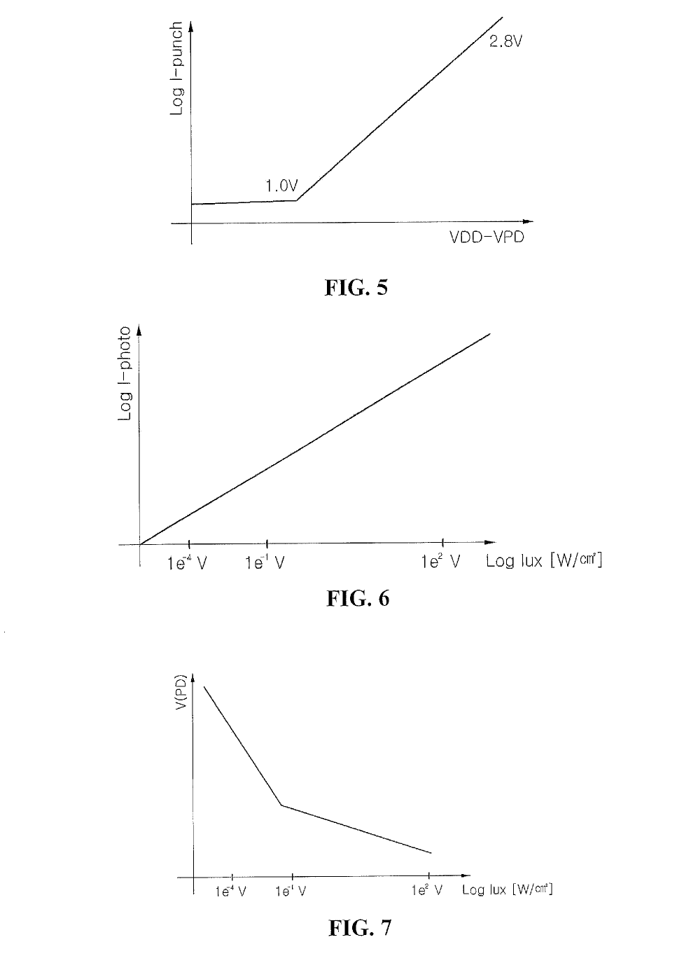

FIG. 5 is a graph illustrating punch-through current with respect to photodiode potential. FIG. 6 is a graph illustrating photo current with respect to luminance (lux) of incident light. FIG. 7 is a graph illustrating photodiode potential with respect to luminance (lux) of incident light.

In contrast to a related-art STI isolation structure, the active pattern 120 may be added to enable a change of the potential due to a doping control. For example, as the N-type doping concentration increases, the potential may be progressively reduced as shown by the potential barriers of c, b, and a in FIG. 4. In FIG. 4, barrier c illustrates a P-type active pattern 120, and b and a barriers illustrate increasing amounts of N-type dopants.

Thus, a structure having the subject punch-through design may have the following two-step characteristics according to applied light.

In the first step, for a potential barrier at level b due to the active pattern 120 having a low energy barrier due to a punch, if electrons are accumulated in the photodiode region 112 below an amount B (or below an amount A for a potential barrier at level a) , the structure has characteristics similar to typical CIS optical characteristics.

In the second step, if electrons are accumulated beyond the amount B for the potential barrier at level b or the amount A for the potential barrier at level a, an overflow current may flow out.

The overflow current depends on the intensity of incident light. The size of the overflow depends on a potential difference between the PD region and VDD region of the transistor region 114.

That is, if the potential difference increases, the overflow increases. Therefore, as shown in FIG. 7, the potential of the PD region 112 may be lowered to a certain level according to the intensity of light. Since the punch-through current increases on a log scale by the potential difference, the voltage reduction in the second step may have a preceding relation with the log scale of the intensity of light, thereby implementing a wide dynamic range.

The above structure may maintain the optical characteristics of a related-art CIS device in a low-lux environment, and may have a low sensitivity and a wide dynamic range in a high-lux environment.

Also, since the saturation voltage (Vsat) increases, it is possible to recognize light of a wider region.

The image sensor and the method for manufacturing the same according to embodiments can ensure a wide dynamic range.

Also, according to embodiments, the doping concentration of the additional active region can be adjusted to control the punch-through characteristics.

In addition, according to embodiments, a wide dynamic range can be secured without an additional mask process.

Hereinafter, a method for manufacturing an image sensor according to an embodiment will be described in detail with reference to FIG. 3.

First, an active region 110 including a photodiode region 112 and a transistor region 114 may be defined on a substrate by a device isolation region 105.

In the defining of the active region 110, an active pattern 120 may be formed to connect the photodiode region 112 to the transistor region 114 at a second location. That is, a separate connection is provided between the photodiode region 112 and the transistor region 114 in addition to the typical related art CIS design (for example, where the photodiode region is connected at a source of a transfer transistor).

For example, the device isolation region 105 may not be formed at a region between the photodiode region 112 and the transistor region 114 to form the active pattern 120.

Thereafter, a photodiode PD may be formed in the photodiode region 112 through an ion implantation, and transistors may be formed in/on the transistor region 114. For example, the transistors may include a transfer transistor 132, a reset transistor 134, a drive transistor 136, and a select transistor 138, but embodiments are not limited thereto. In addition, a floating diffusion FD may be formed in the transistor region 114 at one side of the transfer transistor 132.

In an embodiment, a first conductive-type ion implantation such as an N-type may be performed on the active pattern 120.

The portion of the transistor region 114 to which the active pattern 120 is connected may be a VDD region (connected through contact 142), but is not limited thereto.

In the image sensor and the method for manufacturing the same according to embodiments, a wide dynamic range may be secured.

Also, according to the embodiments, the doping concentration of the additional active region can be adjusted to control the punch-through characteristics.

In addition, according to embodiments, a wide dynamic range can be secured without an additional mask process.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
an active region on a substrate, the active region being defined by a device isolation region;
a photodiode region and a transistor region in the active region;
a photodiode in the photodiode region;
a plurality of transistors on the transistor region; and
an active pattern connecting the photodiode region to the transistor region at a second location.

2. The image sensor according to claim 1, further comprising first conductive-type ions in the active pattern.

3. The image sensor according to claim 1, wherein the device isolation region is not formed under the active pattern.

4. The image sensor according to claim 3, wherein the active pattern serves as a potential barrier between the photodiode region and the transistor region.

5. The image sensor according to claim 4, wherein the active pattern controls the potential barrier using a doping concentration of first conductive-type ions in the active pattern.

6. The image sensor according to claim 4, wherein the active pattern controls the potential barrier using a distance between the photodiode region and the transistor region at the second location.

7. The image sensor according to claim 1, wherein the second location of the transistor region to which the active pattern is connected is a VDD region.

8. A method for manufacturing an image sensor, comprising:
defining an active region on a substrate using a device isolation region, the active region comprising a photodiode region and a transistor region;
forming a photodiode in the photodiode region; and
forming a transistor on the transistor region,
wherein the defining of the active region comprises forming an active pattern connecting the photodiode region to the transistor region at a second location.

9. The method according to claim 8, wherein the forming of the active pattern connecting the photodiode region to the transistor comprises:
forming the active pattern by not forming the device isolation region between a portion of the photodiode region and the transistor region at the second location.

10. The method according to claim 8, after the forming of the active pattern, further comprising performing a first conductive-type ion implantation on the active pattern.

11. The method according to claim 8, wherein the second location of the transistor region to which the active pattern is connected is a VDD region.
